(19) United States
(12) Patent Application Publication
(10) Pub. No.: US 2026/0298786 A1
(43) Pub. Date: Oct. 1, 2026

(54) BOND PULL TEST SYSTEM IN WIRE BONDING OF SEMICONDUCTOR PACKAGE USING MACHINE LEARNING AND TEST METHOD THEREOF

(71) Applicants: SK hynix Inc., Icheon-si (KR); SEOUL NATIONAL UNIVERSITY R&DB FOUNDATION, Seoul (KR)

(72) Inventors: Byung Woo KIM, Icheon-si (KR); Hyunwoo PARK, Seoul (KR)

(21) Appl. No.: 19/195,626

(22) Filed: Apr. 30, 2025

(30) Foreign Application Priority Data
Mar. 31, 2025 (KR) 10-2025-0040977

(51) Int. Cl. G01N 3/08; G06N 20/00

(52) U.S. Cl. CPC G01N 3/08; G06N 20/00

(57) ABSTRACT

A method of testing the tensile strength of a bonding wire included in a semiconductor package is disclosed. The method of testing a tensile strength of a bonding wire included in a disclosed semiconductor package includes: collecting data related to the tensile strength of the bonding wire; consolidating the collected data into a unified database; generating a machine learning model using the unified database, the model configured to determine a tensile strength value of the bonding wire; receiving a tensile strength parameter associated with the bonding wire; predicting a tensile strength value corresponding to the tensile strength parameter using the machine learning model; and determining whether the bonding wire is abnormal based on the predicted strength value.

### CROSS-REFERENCES TO RELATED APPLICATION

The present application claims, under 35 U.S.C. § 119(a), the benefit of Korean Patent Application No. 10-2025-0040977, filed on Mar. 31, 2025 which is hereby incorporated by reference in its entirety.

### BACKGROUND

### 1. Field

Embodiments of the present disclosure relate to a tensile strength testing apparatus and method for a bonding wire included in a semiconductor package.

### 2. Description of the Related Art

Semiconductor packaging is a process in which bonding wires connect a semiconductor chip to an external terminal board, which in turn connects to an external device. The semiconductor chip is then covered with a protective layer made of plastic or other material.

In particular, the wire bonding process is a critical step in semiconductor packaging, requiring a relatively long processing time and playing a key role in the precise control of wire connections.

In this wire bonding process, the tensile strength of the wire is evaluated using a bond pull test. In the conventional bond pull test, a sample is selected from a specific semiconductor packaging area (lot) and tested using a bond pull tester. The user manually attaches a hook to the bonding wire under a microscope, then gradually increases the fulling force until the bonding wire breaks. The tensile strength at the breaking point is recorded as the final tensile strength. If the final tensile strength does not meet the standard value, the sample is deemed defective (failed).

However, conventional bond pull testing methods have a drawback: tested samples become unusable and must be discarded, increasing production costs. As the number of tests increases, the overcall testing expense also increases.

In addition, because destructive testing does not inspect every unit produced, it may lead to reduced reliability and increased costs.

In addition, the conventional bond pull testing methods are performed manually from material procurement through inspection, requiring continuous human labor. This reliance on manual operation presents challenges for process automation and limits the implementation of smart factory systems.

Therefore, to overcome the limitations of the conventional bond pull testing methods, there is a need to develop an apparatus and method that can non-destructively predict the tensile strength of the bonding wire in semiconductor packages using machine learning techniques, while also enabling evaluation of process capability.

### SUMMARY

The technical challenge addressed by the present invention is to provide a tensile strength inspection device for semiconductor package bonding wires that non-destructively predicts a tensile strength value of a bonding wire using machine learning techniques and evaluates process capability.

Furthermore, another technical challenge addressed by the present invention is to provide a method for tensile strength testing of semiconductor package bonding wires having the aforementioned advantages.

A method for testing a tensile strength of a bonding wire included in a semiconductor package, according to one embodiment of the present invention, comprising: collecting data related to the tensile strength of the bonding wire; consolidating the collected data into a unified database; and generating a machine learning model using the unified database, the model configured to determine a tensile strength value of the bonding wire; receiving a tensile strength parameter associated with the bonding wire, predicting a tensile strength value corresponding to the tensile strength parameter using the machine learning model, and determining whether the bonding wire is abnormal based on the predicted tensile strength value.

In this case, the data comprises at least one of data relating to properties of the bonding wire and process variables set during bonding of the bonding wire.

Further, the process variable comprises one or more of temperature, vibration, and ultrasonic frequency set during the bonding of the bonding wire.

Further, the data relating to the properties of the bonding wire may comprise one or more of a diameter of the bonding wire, a loop height, a density, a component, a component ratio.

In addition, if it is determined that the bonding wire is abnormal, a warning message may be output.

Further, the method further comprises updating the predicted tensile strength value to the unified database, and calculating a process capability index using the predicted tensile strength value.

Further, the step of predicting a tensile strength value corresponding to the tensile strength parameter using the machine learning model is characterized in that it comprises extracting one or more features corresponding to the tensile strength parameter and predicting a tensile strength value based on the features.

Further, an apparatus for testing a tensile strength of a bonding wire included in a semiconductor package according to one embodiment of the present invention comprises: an integrated database configured to collect and store data used to determine a tensile strength of the bonding wire; a machine learning module configured to generate a machine learning model for determining the tensile strength value of the bonding wire using the integrated database; a control module configured to predict a tensile strength value corresponding to a tensile strength parameter using the machine learning model, and to determine whether the bonding wire is abnormal based on the predicted tensile strength value.

In this case, the data is characterized by at least one of data relating to properties of the bonding wire and process variables that are set during bonding the bonding wire.

Further, the process variables comprise at least one of temperature, vibration, and ultrasonic frequency set during the bonding of the wire bonding.

Further, characterized in that the data relating to the properties of the bonding wire comprises one or more of a diameter of the bonding wire, a loop height, a density, a component, a component ratio of the wire.

The system may further comprise a warning module configured to output a warning message when the bonding wire is determined to be abnormal.

Further, the control unit is further configured to update the predicted tensile strength value to the integrated database and calculate a process capability index based on the predicted tensile strength value.

Further, the control unit may extract one or more features corresponding to the tensile strength parameter and predict the tensile strength value based on the features.

Further, the machine learning module, the control module, and warning module are implemented using one or more processors.

Embodiments of the present disclosure provide a semiconductor package bonding wire tensile strength inspection device that uses machine learning techniques to non-destructively predict bonding wire tensile strength and evaluate process capability.

Further, embodiments of the present disclosure can provide a method for tensile testing of semiconductor package bonding wires that uses machine learning techniques to non-destructively predict the tensile strength of bonding wires and evaluate process capability.

### BRIEF DESCRIPTION OF THE DRAWINGS

FIG. 1 illustrates a semiconductor package according to one embodiment of the present disclosure.

FIG. 2 illustrates a bond pull test according to one embodiment of the present disclosure.

FIG. 3 illustrates a bonding wire tensile strength testing apparatus according to one embodiment of the present disclosure.

FIG. 4 illustrates a process for testing the tensile strength of a bonding wire in accordance with one embodiment of the present disclosure.

FIG. 5 illustrates an integrated database according to one embodiment of the present disclosure.

FIG. 6 illustrates a process for determining a tensile strength value using machine learning, according to one embodiment of the present disclosure.

FIG. 7 illustrates a tensile strength testing device for semiconductor package bonding wires, according to one embodiment of the present disclosure.

### DETAILED DESCRIPTION

Embodiments of the present disclosure will now be described in detail with reference to the accompanying drawings.

The embodiments of the present disclosure described below are provided for the purpose of more clearly illustrating the invention to those having ordinary skill in the art, and the scope of the invention is not intended to be limited by the following embodiments, which may be modified in various other ways.

The terms used in this specification are intended to describe specific embodiments and are not intended to limit the invention. Terms used herein in the singular form may include the plural form, unless the context clearly indicates otherwise. Furthermore, the terms “comprise” and/or “comprising” as used herein are intended to specify the presence of the mentioned shapes, steps, numbers, motions, absences, elements, and/or groups thereof, and are not intended to exclude the presence or addition of one or more other shapes, steps, numbers, motions, absences, elements, and/or groups thereof. Furthermore, as used herein, the term “connected” is intended to mean not only that certain elements are directly connected, but also that they are indirectly connected by the interposition of other elements between them.

In addition, when the present disclosure refers to a member being located “on” another member, this includes not only when a member is abutting another member, but also when there is another member between the two members. As used herein, the term “and/or” includes any one of the enumerated items and any combination of one or more of them. In addition, the terms “about,” “substantially,” and the like used in the disclosure are intended to mean at or near the range of numbers or degrees, taking into account inherent manufacturing and material tolerances, and to prevent infringers from taking unfair advantage of the disclosure where precise or absolute numbers are stated, which are provided for the purpose of illustration.

Embodiments of the present invention will now be described in detail with reference to the accompanying drawings. The sizes or thicknesses of the areas or parts shown in the accompanying drawings may be somewhat exaggerated for clarity and ease of description. Throughout the detailed description, reference numerals designate like components.

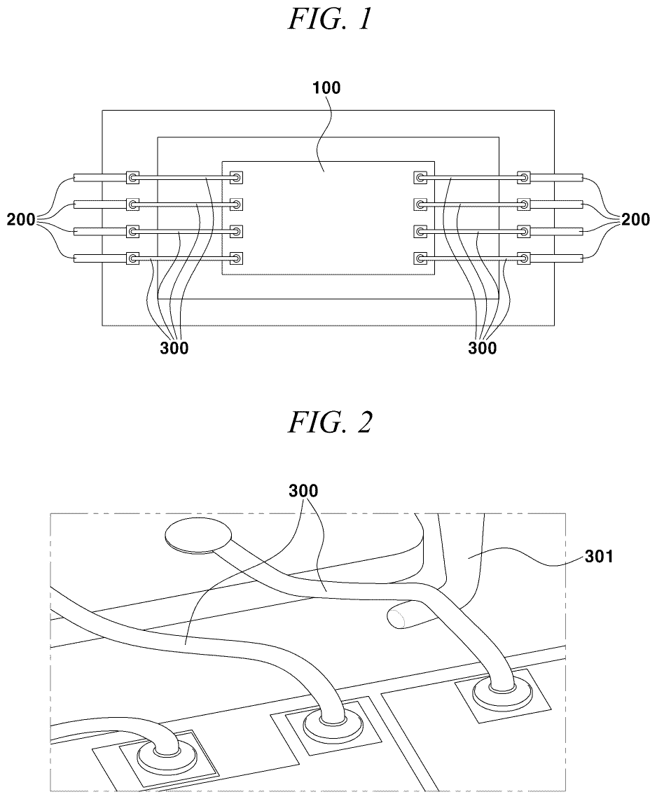

FIG. 1 illustrates a semiconductor package according to one embodiment of the present disclosure. Referring to FIG. 1, a semiconductor device 100, such as a semiconductor chip or integrated circuit (IC), is connected to a substrate 200 via bonding wires 300.

The bonding wire 300 may be formed from various conductive materials, including, but not limited to, gold, copper, and the like, and may vary in composition, density, and other properties. The bonding wire 300 should have a tensile strength value above a predetermined threshold to maintain the performance of the semiconductor package. Notably, the wire bonding process is a critical process in the semiconductor package manufacturing process, requiring precise wire control and a relatively long process time.

FIG. 2 illustrates a bond pull test according to one embodiment of the present disclosure.

Referring to FIG. 2, the tensile strength of a wire 300 is evaluated using a bond pull test. In this test, a hook 301 is attached to the wire 300 using a predetermined tool, and the wire 300 is pulled vertically with gradually increasing force, starting from a low level. The forth at which the wire 300 breaks is recorded as the final tensile strength. If the final tensile strength does not exceed a predetermined threshold value, the wire 300 is deemed defective (i.e., it fails the test).

This bond pull test has several disadvantages. Since the tested sample is destroyed during the test, it cannot be reused and must be discarded, leading to increased production costs. Additionally, the cost of the test rises proportionally with the number of samples tested. Because the test is destructive, it cannot be applied to all manufactured products, which reduces reliability and further increases costs. Moreover, the entire process from material procurement to inspection is performed manually, requiring continuous human labor and presenting a challenge to process automation and the implementation of smart factory systems.

Therefore, to solve these issues, the present disclosure provides a machine learning-based apparatus and method for inspecting the tensile strength of semiconductor bonding wires. By applying machine learning techniques, the tensile strength can be predicted non-destructively, enabling evaluation of the process capability without damaging the samples.

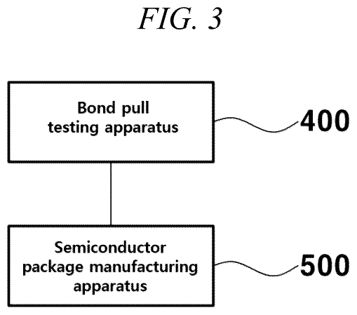

FIG. 3 illustrates a wire tensile strength testing apparatus according to one embodiment of the present disclosure. Referring to FIG. 3, a bond pull testing apparatus 400 may non-destructively predict a tensile strength value of a bonding wire by applying machine learning techniques to data obtained from a semiconductor package manufacturing apparatus 500.

Although machine learning is described herein as being used to predict the tensile strength value of the bonding wire, it is equally applicable to apparatuses and methods for testing the strength of bonding balls used in wire bonding processes. Accordingly, the present disclosure is not limited to bonding wires alone.

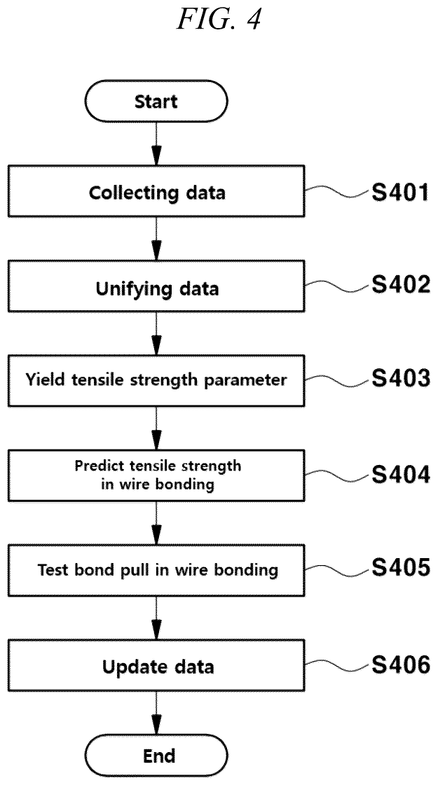

FIG. 4 illustrates a process for testing the tensile strength of a bonding wire according to one embodiment of the present disclosure. Referring to FIG. 4, at step S401, a bond pull testing apparatus collects data necessary to determine a tensile strength value of a bonding wire in real time, performs preprocessing on the collected data, and constructs a unified database.

For example, a bond pull testing apparatus according to one embodiment of the present disclosure may collect, in real time, data necessary to determine a tensile strength value of a bonding wire from each piece of equipment or systems associated with the semiconductor package manufacturing process (e.g., MES, EMS, QMS, FDC).

The collected data may pertain to key process variables that occur during the wire bonding step (e.g., temperature, vibration, ultrasonic frequency, bonding pressure applied to the wire during bonding, and other equipment setup information). It may also relate to the physical properties of the wire (e.g., diameter, loop height, density, etc.) or its chemical properties (e.g., composition, composition ratio, etc.). In general, any type of data used to determine the tensile strength value of the bonding wire may be included.

In this case, the criteria for the data collected to determine the tensile strength value of the bonding wire may be determined based on standard technical documents (e.g., JEDEC, Mil-standard, etc.). Furthermore, an embodiment of the present disclosure may include the process of using machine learning techniques to extract the data used to determine the tensile strength value of the bonding wire from these standard technical documents or from a database that stores and updates the standard technical documents in real time.

Each piece of equipment or systems associated with the semiconductor package manufacturing process, from which the above data is collected, may include a production management system (MES), an equipment management system (EMS), a quality management system (QMS), a defect detection (FDC) data system, and the like. In addition, such equipment or systems may be networked with the bonding wire tensile strength inspection apparatus according to one embodiment of the present disclosure and configured to transmit the collected data in real time.

Next, at step S402, the bonding wire tensile strength testing apparatus according to one embodiment of the present disclosure consolidates the collected data into a unified database. For example, the collected data is consolidated into the unified database using basic identifiers such as lot ID, machine ID, etc. At this stage, the collected data may undergo further preprocessing to ensure data quality, including deduplication, handling of missing values, standardization, and scaling.

Next, the bonding wire tensile strength testing apparatus utilizes the unified database to develop a machine learning model for predicting the tensile strength value.

In this case, a variety of machine learning techniques may be used to develop the machine learning model for predicting the tensile strength value. For example, regression analysis techniques may be used. Regression analysis is a technique that can provide accurate predictions by reflecting the continuous nature and correlations within the data. This technique is suitable for predicting continuous output variables, such as the tensile strength value of the bonding wire. It is particularly advantageous for identifying linear or weakly nonlinear relationships between the data used to determine the tensile strength value of the bonding wire (data related to wire characteristics or process variables set during the bonding process) and the tensile strength value of the bonding wire.

On the other hand, in wire bonding tensile strength prediction, the relationship between the tensile strength value and the data or process variables associated with the properties of the bonding wire is often too complex to be described by a simple linear relationship. Therefore, ensemble techniques, such as random forest, XGBoost, etc., which are well-suited for handling complex nonlinear relationships, may be applied. These techniques combine multiple learners (e.g., decision trees) to create a more powerful and flexible model capable of effectively capturing the intricate nonlinear relationships between the tensile strength value and the data or process variables associated with the properties of the bonding wire.

Ensemble techniques can enhance prediction performance by learning various patterns in the data and are effective at handling outliers (data beyond the upper and lower control limits). Ensemble techniques, such as random forests, are particularly useful for managing variability and uncertainty in process data. They aggregate the results of multiple decision trees to make a final prediction, resulting in a more stable and reliable prediction of the tensile strength value of the bonding wire, with less variability than a single model.

Next, at step S403, the bonding wire tensile strength testing apparatus receives a tensile strength parameter associated with the bonding wire that is currently subject to tensile strength testing.

For example, the tensile strength parameter may include any type of data used to determine the tensile strength value of the bonding wire being inspected. The tensile strength parameter may include data related to key process variables that occur during the wire bonding step, such as temperature, vibration, ultrasonic frequency, bonding pressure applied to the wire during bonding, other equipment setup information, etc.

Next, at step S404, the bonding wire tensile strength testing apparatus inputs the tensile strength parameter associated with the bonding wire currently subject to tensile strength testing into a machine learning model. Based on the machine learning process, the bonding wire tensile strength testing apparatus predicts a tensile strength value corresponding to the tensile strength parameter.

As described above, a machine learning model for predicting tensile strength may employ various machine learning techniques, such as regression analysis. Regression analysis is a technique that can provide accurate predictions by capturing the continuous nature and correlations within the data. It is suitable for continuous output variables such as the tensile strength value of the bonding wire, and is particularly effective in identifying linear or weakly nonlinear relationships between the data used to determine the tensile strength value(e.g., wire characteristics or process variables set during the bonding of the wire) and the tensile strength value itself.

On the other hand, in wire bonding tensile strength prediction, the relationship between the tensile strength value and the data or process variables related to the properties of the wire is often too complex to be described by a simple linear relationship. Therefore, ensemble techniques, such as random forest, XGBoost, etc., which are designed to handle complex nonlinear relationships, can be applied. These techniques combine multiple learners (e.g., decision trees) to create a more powerful and flexible model that can effectively manage the intricate nonlinear relationships between the tensile strength value and the data or process variables related to the properties of the wire.

Ensemble techniques can enhance prediction performance by learning various patterns in the data and are effective at processing a higher number of outliers (data beyond the upper and lower control limits). Ensemble techniques, such as random forests, are particularly well-suited for managing variability and uncertainty in process data. By averaging or voting on the results from multiple decision trees, these techniques provide a stable prediction of the tensile strength value of the bonding wire, with reduced variability compared to a single model.

When a tensile strength parameter is input to the machine learning model, as described above, the model derives a corresponding tensile strength value as a predicted tensile strength value.

The parameters of the bonding wire, such as the key process variables that occur during the bonding phase (e.g., temperature, vibration, ultrasonic frequency, bonding pressure applied to the wire during bonding, other equipment setup information, etc.), are used as input data for the model.

Next, at step S405, the bonding wire tensile strength inspection apparatus according to one embodiment of the present disclosure may perform bond pull testing in wire bonding. Specifically, the bonding wire tensile strength inspection apparatus may evaluate the predicted tensile strength value against the quality control standards of the semiconductor package manufacturing process. If the predicted tensile strength value falls outside the predefined lower and upper limits, the apparatus identifies an abnormality and classifies the corresponding bonding wire or the corresponding semiconductor package product as defective.

Therefore, the bonding wire tensile strength inspection apparatus may construct a machine learning model based on the data collected in real time, and derive a predicted tensile strength value using the data parameters input in real time. By using the predicted tensile strength value, the boding wire tensile strength inspection apparatus may continuously monitor the process status, and evaluate the process quality in real time through the machine learning model.

In some embodiments, if the predicted tensile strength value falls outside the predefined lower and upper limits, an anomaly may be detected, and a warning message may be automatically sent to the user for immediate verification and response.

Next, at step S406, the bonding wire tensile strength testing apparatus may update the predicted tensile strength value to the unified database.

In accordance with embodiments, a process capability index (Cpk) may be calculated based on the predicted tensile strength value to evaluate the variability and stability of a semiconductor package manufacturing process. The process capability index (Cpk) may be used to determine whether the semiconductor package manufacturing process is operating within acceptable limits and to proactively identify potential issues.

In addition, according to an embodiment, the predicted tensile strength value and actual process data may be visualized and output as a statistical process control (SPC) chart, such as an X-bar chart. Therefore, the bonding wire tensile strength testing apparatus may detect abnormalities or signs of process instability by comparing the predicted value with the actual data and setting control limits in real time, thereby enabling continuous monitoring of whether the semiconductor package manufacturing process remains within a stable range.

Thus, according to the present invention, by automatically evaluating the wire bonding process, it is possible to enhance semiconductor package productivity, reduce manufacturing costs, ensure consistency in quality assessment, and support the implementation of smart factory systems.

In addition, according to the present invention, when an abnormality is detected in the tensile strength value of the bonding wire, the corresponding abnormal data and corrective action results are updated in the unified database and reflected in the machine learning model. This feedback mechanism enhances the performance of the machine learning model over time, enabling continuous improvement in process management.

As such, the present invention facilitates the establishment of an automated quality assessment system by analyzing data collected in real time during the semiconductor package manufacturing process and predicting the tensile strength value of the bonding wire using a machine learning model. The prediction results are evaluated using process capability index (Cpk) analysis and statistical process control charts, with automatic alerts issued in the event of an abnormality. Therefore, this automated quality assessment system contributes to increased productivity, improved quality stability, and the implementation of smart factory systems. Additionally, it supports cost reduction and resource efficiency through non-destructive inspection methods.

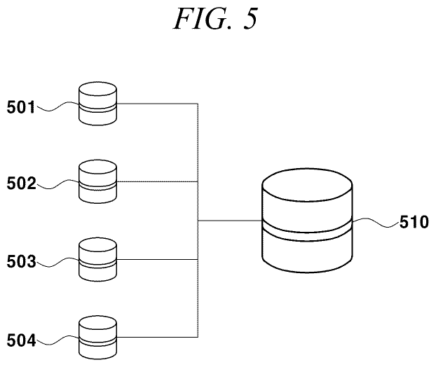

FIG. 5 illustrates a unified database according to one embodiment of the present disclosure. Referring to FIG. 5, a bonding wire tensile strength testing device according to one embodiment of the present disclosure may collect, in real time, data from a plurality of systems (501, 502, 503, 504) and construct a unified database (510).

For example, the bonding wire tensile strength testing device may collect, in real time, data necessary to determine a tensile strength value of a bonding wire from each piece of equipment or system (501, 502, 503, 504) associated with the semiconductor package manufacturing process.

In this case, the collected data may be related to key process variables that occur during the wire bonding step, such as temperature, vibration, ultrasonic frequency, bonding pressure applied to the wire during bonding, other equipment setup information, etc. In addition, the data may include physical properties of the bonding wire (e.g., diameter, loop height, density, etc.) or chemical properties (e.g., composition, composition ratio, etc.). Any type of data used to determine the tensile strength value of the bonding wire may be included.

In this case, the criteria for the data collected to determine the tensile strength value of the bonding wire may be determined based on standard technical documents (e.g., JEDEC, Mil-standard, etc.). Furthermore, an embodiment of the present disclosure may include the process of using machine learning techniques to extract the data used to determine the tensile strength value of the bonding wire from these standard technical documents or from a database that stores and updates the standard technical documents in real time.

The respective equipment or systems associated with the semiconductor package manufacturing process, from which the above data is collected, may include, but are not limited to, a production management system (MES), an equipment management system (EMS), a quality management system (QMS), a defect detection (FDC) data system, and the like. These systems may be internally or externally networked with the bonding wire tensile strength testing apparatus according to one embodiment of the present invention and may be configured to transmit such data in real time.

The bonding wire tensile strength testing apparatus according to one embodiment of the present disclosure consolidates the collected data into the unified database (510).

For example, the collected data is consolidated into the unified database (510) using basic identifiers such as lot ID, machine ID, etc. At this stage, the collected data may undergo further preprocessing to ensure data quality, including deduplication, handling of missing values, standardization, and scaling.

It has already been described that the bonding wire tensile strength testing apparatus according to one embodiment of the present disclosure may utilize such an integrated database, e.g., the unified database (510), to form a machine learning model for predicting the tensile strength value of the bonding wire.

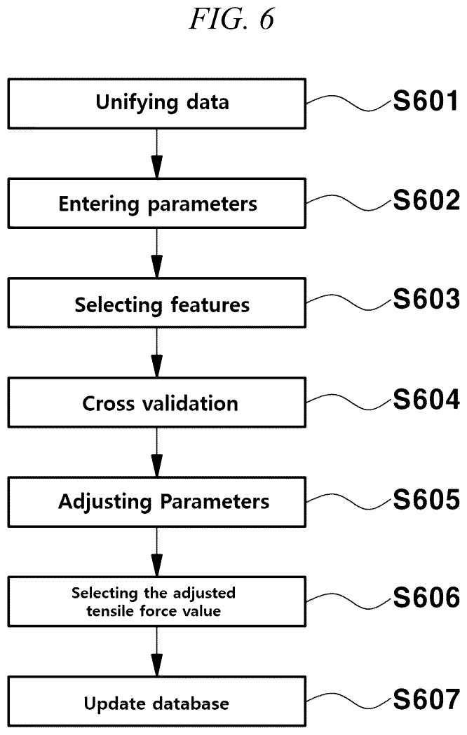

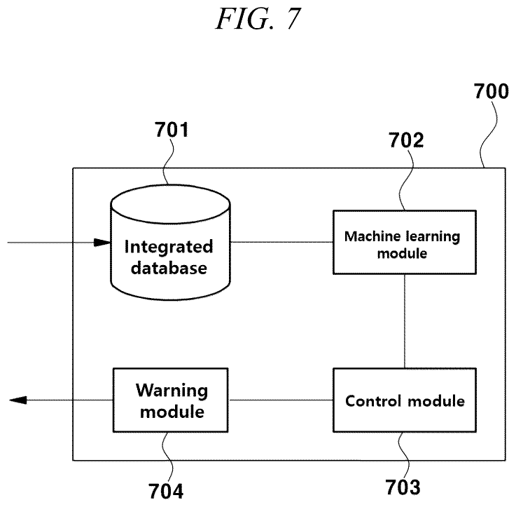

FIG. 6 illustrates a process for determining a tensile strength value using machine learning, according to one embodiment of the present disclosure.

Referring to FIG. 6, the bonding wire tensile strength testing apparatus according to one embodiment of the present disclosure may collect, in real time, data from a plurality of systems at step S601 and construct a unified database. For example, the bonding wire tensile strength testing apparatus may collect, in real time, data necessary to determine the tensile strength value of the bonding wire from each piece of equipment or system (501, 502, 503, 504) associated with the semiconductor package manufacturing process.

In this case, the collected data may include key process variables that occur during the wire bonding step, such as temperature, vibration, ultrasonic frequency, bonding pressure applied to the wire, other equipment setup information, etc. In addition, the date may include the physical properties of the wire (e.g., diameter, loop height, density, etc.) or chemical properties (e.g., composition, composition ratio, etc.). In general, any type of data used to determine the tensile strength value of the bonded wire may be included.

In this case, the criteria for the data collected to determine the tensile strength value of the bonding wire may be determined based on standard technical documents (e.g., JEDEC, Mil-standard, etc.). Furthermore, an embodiment of the present disclosure may include the process of using machine learning techniques to extract the data used to determine the tensile strength value of the bonding wire from these standard technical documents or from a database that stores and updates the standard technical documents in real time.

The respective equipment or systems associated with the semiconductor package manufacturing process, from which the above data is collected, may include, but are not limited to, a production management system (MES), an equipment management system (EMS), a quality management system (QMS), a defect detection (FDC) data system, and the like. These systems may be internally or externally networked with the bonding wire tensile strength testing apparatus according to one embodiment of the present disclosure and may be configured to transmit the collected data in real time.

The bonding wire tensile strength testing apparatus according to one embodiment of the present disclosure may consolidate the collected data into the unified database.

For example, the collected data is consolidated into the unified database using basic identifiers such as lot ID, machine ID, etc. At this stage, the collected data may undergo further preprocessing to ensure data quality, including deduplication, handling of missing values, standardization, and scaling.

It has already been described that the bonding wire tensile strength testing device according to one embodiment of the present disclosure may utilize such an integrated database to form a machine learning model for predicting the tensile strength value of the bonding wire.

Next, at step S602, the bonding wire tensile strength testing apparatus may input the tensile strength parameter associated with the bonding wire currently subject to tensile strength testing into the machine learning model.

At step S603, the machine learning model may determine one or more features corresponding to the tensile strength parameter. At step S604, the machine learning model may perform cross-validation of these features across multiple decision trees to ensure their validity. Based on the validation results, the machine learning model may adjust and verify the parameters at step S605 through hyper-parameter optimization. Finally, at step S606, the machine learning model may select the adjusted value as the tensile strength value of the bonding wire.

In this case, the features used to determine the tensile strength value of the bonding wire may be determined based on standard technical documents (e.g., JEDEC, Mil-standard, etc.). The process of using machine learning techniques to extract the features from these standard technical documents or from a database that stores and updates the standard technical documents in real time may also be included as an embodiment of the present disclosure.

As described above, a machine learning model for predicting tensile strength may employ various machine learning techniques, including regression analysis. Regression analysis is suitable for continuous output variables such as the tensile strength value of the bonding wire, as it enables accurate prediction by capturing the continuous nature and correlations within the data. This technique is particularly advantageous for identifying linear or weakly nonlinear relationships between input variables, such as wire characteristics and process variables set during the bonding of the wire, and the tensile strength value.

On the other hand, in wire bonding tensile strength prediction, the relationship between the tensile strength value and the data or process variables associated with the properties of the wire is often too complex to be described by a simple linear relationship. Therefore, ensemble techniques, such as random forest, XGBoost, etc., which are well-suited for handling complex nonlinear relationships, may be applied. These techniques combine multiple learners (e.g., decision trees) to create a more powerful and flexible model capable of effectively capturing the intricate nonlinear relationships between the tensile strength value and the data or process variables associated with the properties of the wire.

Ensemble techniques can enhance prediction performance by learning various patterns in the data and are effective at handling outliers (data beyond the upper and lower control limits). Ensemble techniques, such as random forests, are particularly useful for managing variability and uncertainty in process data. They aggregate the results of multiple decision trees to make a final prediction, resulting in a more stable and reliable prediction of the tensile strength value of the bonding wire, with less variability than a single model.

When a tensile strength parameter is input to the machine learning model as described above, the machine learning model generates a predicted tensile strength value corresponding to the input tensile strength parameter.

The input parameter associated with the current bonding wire may include key process variables that occur during the bonding step, such as temperature, vibration, ultrasonic frequency, bonding pressure, other equipment setup information, etc. In addition, the parameters may include the physical properties of the wire (e.g., diameter, loop height, density, etc.) or chemical properties (e.g., composition, composition ratio, etc.). Any type of data used to determine the tensile strength value of the bonded wire may be used as input to the machine learning model.

Next, at step S605, the bonding wire tensile strength inspection apparatus according to one embodiment of the present disclosure may evaluate the predicted tensile strength value against the quality control criteria of the semiconductor package manufacturing process. If the predicted tensile strength value falls outside the predefined lower and upper limits, the apparatus may determine that an anomaly has occurred, determine that the corresponding bonding wire or the corresponding semiconductor package product is defective, and update the predicted tensile strength value to the unified database.

Therefore, the bonding wire tensile strength inspection device may continuously monitor the process status by building a machine learning model based on the data collected in real time, deriving a predicted tensile strength value based on real-time input parameters, and analyzing the process quality in real time based on the predicted tensile strength value of the bonding wire through the machine learning model.

In accordance with embodiments, a process capability index (Cpk) may be calculated based on the predicted tensile strength value to evaluate the variability and stability of the semiconductor package manufacturing process. The process capability index (Cpk) may be used to determine whether the semiconductor package manufacturing process is operating within acceptable limits and to proactively identify potential issues.

In addition, according to an embodiment, the predicted tensile strength value and actual process data may be visualized and output as a statistical process control chart, such as an X-bar chart, to detect abnormalities or signs of process instability by comparing the predicted value with the actual data and setting control limits in real time, thereby enabling continuous monitoring of whether the semiconductor package manufacturing process is within a stable range.

FIG. 7 illustrates a tensile strength testing device (700) for semiconductor package bonding wires, according to one embodiment of the present disclosure.

Referring to FIG. 7, the testing device (700) may include an integrated database (701), a machine learning module (702), a control module (703), and a warning module (704).

The integrated database (701) may collect data to determine a tensile strength value of a bonding wire and store the collected data.

In this case, the testing device (700) may collect data necessary to determine the tensile strength value of the bonding wire in real time from each piece of equipment or systems associated with the semiconductor package manufacturing process.

The collected data may be related to key process variables that occur during the wire bonding step, such as temperature, vibration, ultrasonic frequency, bonding pressure, other equipment setup information, etc. In addition, the data may include the physical properties of the bonding wire (e.g., diameter, loop height, density, etc.) or chemical properties (e.g., composition, composition ratio, etc.). Any type of data used to determine the tensile strength value of the bonding wire may be included.

In this case, the criteria for the data collected to determine the tensile strength value of the bonding wire may be determined based on standard technical documents (e.g., JEDEC, Mil-standard, etc.). Furthermore, an embodiment of the present disclosure may include the process of using machine learning techniques to extract the data used to determine the tensile strength value of the bonding wire from these standard technical documents or from a database that stores and updates the standard technical documents in real time.

The respective equipment or systems associated with the semiconductor package manufacturing process, from which the above data is collected, may include, but are not limited to, a production management system (MES), an equipment management system (EMS), a quality management system (QMS), a defect detection (FDC) data system, and the like. These systems may be internally or externally networked with the testing device (700) and may be configured to transmit such data in real time.

The testing device (700) consolidates the collected data into the integrated database (701).

For example, the collected data may be consolidated into the integrated database (701) using basic identifiers such as lot ID, machine ID, etc. At this stage, the collected data may undergo further preprocessing to ensure data quality, including deduplication, handling of missing values, standardization, and scaling.

The machine learning module (702) utilizes the integrated database (701) to generate a machine learning model used to detect the tensile strength value of the bonding wire.

It has already been described that the testing device (700) may utilize such an integrated database, e.g., the integrated database (701), to form a machine learning model for predicting the tensile strength value of the bonding wire.

Next, the control module (703) may receive a parameter related to the tensile strength value of the bonding wire, predict a tensile strength value corresponding to the parameter using the machine learning model, and determine whether the bonding wire is abnormal based on the predicted tensile strength value.

The machine learning module (702) may determine one or more features corresponding to the tensile strength parameter, perform cross-validation of the features across a plurality of decision trees to ensure their validity, adjust the parameters based on the validation results, and select the adjusted value as the predicted tensile strength value of the bonding wire.

In this case, the features used to determine the tensile strength value of the bonding wire may be determined based on standard technical documents (e.g., JEDEC, Mil-standard, etc.). The process of using machine learning techniques to extract the features from these standard technical documents or from a database that stores and updates the standard technical documents in real time may also be included as an embodiment of the present disclosure.

As described above, a machine learning model for predicting tensile strength may employ various machine learning techniques, including regression analysis techniques. Regression analysis is suitable for continuous output variables such as the tensile strength value of the bonding wire, as it enables accurate prediction by capturing the continuous nature and correlations within the data. This technique is particularly advantageous for identifying linear or weakly nonlinear relationships between input variables, such as wire characteristics and process parameters set during the bonding of the wire, and the tensile strength value.

On the other hand, in wire bonding tensile strength prediction, the relationship between the tensile strength value and the data or process variables associated with the properties of the wire is often too complex to be described by a simple linear relationship. Therefore, ensemble techniques, such as random forest, XGBoost, etc., which are well-suited for handling complex nonlinear relationships, may be applied. These techniques combine multiple learners (e.g., decision trees) to create a more powerful and flexible model capable of effectively capturing the intricate nonlinear relationships between the tensile strength value and the data or process variables associated with the properties of the wire.

Ensemble techniques can enhance prediction performance by learning various patterns in the data and are effective at handling outliers (data beyond the upper and lower control limits). Ensemble techniques, such as random forests, aggregate the results of multiple decision trees typically by averaging or voltage-to make a final prediction. These techniques are effective in handling the variability and uncertainty of process data, as they can predict the tensile strength value of the bonding wire more reliably and with reduced variability compared to a single model.

When a tensile strength parameter is input to the machine learning module (702) as described above, the machine learning module (702) generates a predicted tensile strength value corresponding to the input tensile strength parameter.

The input parameters associated with the current bonding wire may include key process variables that occur during the bonding step, such as temperature, vibration, ultrasonic frequency, bonding pressure, other equipment settings, etc.

The control unit (703) may evaluate the predicted tensile strength value against the quality control criteria of the semiconductor package manufacturing process, If the predicted tensile strength value is outside the predefined lower and upper limits, the control unit (703) determines that an anomaly has occurred, determines that the bonding wire or the corresponding semiconductor package product is defective, and updates the predicted tensile strength value to the integrated database (701).

Therefore, the bonding wire tensile strength inspection device according to one embodiment of the present disclosure may continuously monitor the process status by building a machine learning model based on the data collected in real time, deriving a predicted tensile strength value using real-time input parameters input, and analyzing the process quality in real time based on the predicted tensile strength value of the bonding wire through the machine learning model.

Further, after updating the predicted tensile strength value to the integrated database (701), the control module (703) may calculate a process capability index using the predicted tensile strength value.

In other words, the present invention may calculate a process capability index (Cpk) based on the predicted tensile strength value to evaluate the variability and stability of a semiconductor package manufacturing process. The process capability index (Cpk) may be used to determine whether the semiconductor package manufacturing process is operating within acceptable limits and to identify potential issues in advance.

In addition, according to an embodiment, the predicted tensile strength value and actual process data may be visualized and output as a statistical process control chart, such as an X-bar chart, to detect abnormalities or signs of process instability by comparing the predicted value with the actual data and setting control limits in real time, thereby enabling continuous monitoring of whether the semiconductor package manufacturing process is within a stable range.

The warning module (704) may output a warning message when the bonding wire is determined to be abnormal.

In an embodiment of the present disclosure, the machine learning module (702), the control module (703), and the warning module (704) may be implemented using one or more processors.

This description discloses preferred embodiments of the present invention, and although certain terms are used, they are used in a general sense only to facilitate the description and understanding of the invention and are not intended to limit the scope of the invention. In addition to the embodiments disclosed herein, other modifications based on the technical ideas of the present invention will be apparent to those of ordinary skill in the art to which the present invention belongs. It will be apparent to one having ordinary knowledge in the art that the apparatus and method for testing the tensile strength of a semiconductor package bonding wire according to the embodiments described with reference to FIGS. 1 through 7 may be subject to various substitutions, changes, and modifications without departing from the technical ideas of the invention. The scope of the invention is therefore not limited by the embodiments described, but by the technical ideas recited in the patent claims.

What is claimed is:

1. A method for testing a tensile strength of a bonding wire included in a semiconductor package, the method comprising:
collecting data related to the tensile strength of the bonding wire;
consolidating the collected data into a unified database;
generating a machine learning model using the unified database, the model configured to determine a tensile strength value of the bonding wire;
receiving a tensile strength parameter associated with the bonding wire;
predicting a tensile strength value corresponding to the tensile strength parameter using the machine learning model; and
determining whether the bonding wire is abnormal based on the predicted tensile strength value.

2. The method of claim 1, wherein the data comprises one or more of data relating to properties of the bonding wire and process variables set during bonding of the bonding wire.

3. The method of claim 2, wherein the process variables comprise one or more of temperature, vibration, and ultrasonic frequency set during the bonding of the bonding wire.

4. The method of claim 2, wherein the data relating to the properties of the bonding wire comprises one or more of a diameter of the bonding wire, a loop height, a density, a material component, and a component ratio.

5. The method of claim 1, further comprising:
output a warning message in response to determining that the bonding wire is abnormal.

6. The method of claim 1, further comprising:
updating the predicted tensile strength value to the unified database; and
calculating a process capability index using the predicted tensile strength value.

7. The method of claim 1, wherein predicting the tensile strength value corresponding to the tensile strength parameter using the machine learning model comprises:
extracting one or more features corresponding to the tensile strength parameter; and
predicting the tensile strength value based on the features.

8. An apparatus for testing a tensile strength of a bonding wire included in a semiconductor package, the apparatus comprising:
an integrated database configured to collect and store data used to determine a tensile strength value of the bonding wire;
a machine learning module configured to generate a machine learning model for determining the tensile strength value of the bonding wire using the integrated database; and
a control module configured to predict a tensile strength value corresponding to a tensile strength parameter using the machine learning model, and to determine whether the bonding wire is abnormal based on the predicted tensile strength value.

9. The apparatus of claim 8, wherein the data includes one or more of data relating to properties of the bonding wire and process variables that are set during bonding of the bonding wire.

10. The apparatus of claim 8, wherein the process variables comprise one or more of temperature, vibration, and ultrasonic frequency set during the bonding of the bonding wire.

11. The apparatus of claim 9, wherein the data relating to the properties of the bonding wire comprises one or more of a diameter of the bonding wire, a loop height, a density, a material component, and a component ratio of the wire.

12. The apparatus of claim 8, further comprising:
a warning module configured to output a warning message when the bonding wire is determined to be abnormal.

13. The apparatus of claim 8, wherein the control unit is further configured to update the predicted tensile strength value to the integrated database and calculate a process capability index based on the predicted tensile strength value.

14. The apparatus of claim 8, wherein the control unit is further configured to extract one or more features corresponding to the tensile strength parameter and predict the tensile strength value based on the features.

15. The apparatus of claim 12, wherein the machine learning module, the control module, and warning module are implemented using one or more processors.
